(19) United States
(12) Patent Application Publication
(10) Pub. No.: US 2024/0304915 A1
(43) Pub. Date: Sep. 12, 2024

(54) BATTERY PACK

(71) Applicant: Prime Planet Energy & Solutions, Inc., Tokyo (JP)

(72) Inventors: Naotake YOSHIDA, Himeji-shi (JP); Satoru MATSUYAMA, Kasai-shi (JP)

(21) Appl. No.: 18/581,388

(22) Filed: Feb. 20, 2024

(30) Foreign Application Priority Data
Mar. 7, 2023 (JP) 2023-034454

(51) Int. Cl. H01M 50/209; G01R 31/364; H01M 50/507; H01M 50/51; H01M 50/55

(52) U.S. Cl. CPC H01M 50/209; G01R 31/364; H01M 50/507; H01M 50/51; H01M 50/55

(57) ABSTRACT

A battery pack includes: a first stack and a second stack each including a plurality of battery cells arranged side by side in a first direction; a case that accommodates the first stack and the second stack; a plurality of bus bars that electrically connect the plurality of battery cells; a first plate on which a first group of the plurality of bus bars is mounted; and a second plate on which a second group of the plurality of bus bars is mounted, the second plate being separated from the first plate, the second group being different from the first group, wherein each of the first plate and the second plate extends along a second direction orthogonal to the first direction so as to reach the second stack from the first stack, and the first plate and the second plate are arranged side by side along the first direction.

### CROSS REFERENCE TO RELATED APPLICATIONS

This nonprovisional application is based on Japanese Patent Application No. 2023-034454 filed on Mar. 7, 2023 with the Japan Patent Office, the entire contents of which are hereby incorporated by reference.

### BACKGROUND OF THE INVENTION

### Field of the Invention

The present technology relates to a battery pack.

### Description of the Background Art

Japanese Patent Laying-Open No. 2021-136162 discloses a case that is assembled to a battery assembly constituted of a plurality of cells and that supports a bus bar, wherein the case is constituted of a plurality of divided cases that are divided in an arrangement direction of the cells and that are coupled by a coupling portion.

In Japanese Patent Laying-Open No. 2021-136162, with the above-described configuration, a tolerance of each of electrodes of the cells is absorbed, with the result that a bus bar module can be assembled excellently to the battery assembly.

### SUMMARY OF THE INVENTION

When bus bars provided as collective terminals for both polarities of battery assemblies are drawn out from one side in a transverse direction orthogonal to a stacking direction of the battery cells, a bus bar is likely to be long. With the bus bar long in length, efficiency in mounting battery cells and other components can be decreased.

Regarding a battery pack in which a plurality of battery assemblies are arranged side by side in a transverse direction orthogonal to a stacking direction of battery cells, there is still room for improvement in a conventional battery pack from a viewpoint of improving efficiency in mounting battery cells and other components.

It is an object of the present technology to provide a battery pack having high efficiency in mounting battery cells and other components.

The present technology provides the following battery pack.
[1] A battery pack comprising: a first stack and a second stack each including a plurality of battery cells arranged side by side in a first direction; a case that accommodates the first stack and the second stack; a plurality of bus bars that electrically connect the plurality of battery cells; a first plate on which a first group of the plurality of bus bars is mounted; and a second plate on which a second group of the plurality of bus bars is mounted, the second plate being separated from the first plate, the second group being different from the first group, wherein each of the first plate and the second plate extends along a second direction orthogonal to the first direction so as to reach the second stack from the first stack, and the first plate and the second plate are arranged side by side along the first direction.
[2] The battery pack according to [1], wherein the plurality of battery cells included in the first stack and the second stack are electrically connected in series by the plurality of bus bars, and a positive-electrode-side collective terminal and a negative-electrode-side collective terminal of the plurality of battery cells connected in series are located on the same side with respect to the first stack and the second stack in the second direction.
[3] The battery pack according to [1] or [2], wherein each of the first group and the second group of the plurality of bus bars includes a bus bar that connects a battery cell included in the first stack to a battery cell included in the second stack.
[4] The battery pack according to any one of [1] to [3], further comprising: a first connector in which first voltage detection lines for the plurality of battery cells to which the first group of the plurality of bus bars is connected are collected; and a second connector in which second voltage detection lines for the plurality of battery cells to which the second group of the plurality of bus bars is connected are collected.
[5] The battery pack according to any one of [1] to [4], wherein each of the first stack and the second stack includes even and same number of battery cells, and widths of the first plate and the second plate in the first direction are the same.
[6] The battery pack according to any one of [1] to [4], wherein each of the first stack and the second stack includes odd and same number of battery cells, and widths of the first plate and the second plate in the first direction are different from each other.
[7] The battery pack according to any one of [1] to [6], wherein the case supports the first stack and the second stack in the first direction.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view of a battery assembly.

FIG. 2 is a perspective view showing a battery cell included in the battery assembly.

FIG. 3 is a perspective view showing a case member (except for a cover portion) of a battery pack.

FIG. 4 is a diagram showing an arrangement of bus bar plates and bus bars in the battery pack according to the present embodiment.

Each of FIGS. 5 and 6 is a diagram showing an arrangement of bus bar plates and bus bars in a battery pack according to a reference example.

FIG. 7 is a top view showing an arrangement of bus bar plates and bus bars in a battery pack according to a modification.

FIG. 8 is a diagram showing a state in which voltage detection lines and a connector shown in FIG. 7 are viewed from a lateral side (X axis direction) of each battery cell.

### DESCRIPTION OF THE PREFERRED EMBODIMENTS

Hereinafter, embodiments of the present technology will be described. It should be noted that the same or corresponding portions are denoted by the same reference characters, and may not be described repeatedly.

It should be noted that in the embodiments described below, when reference is made to number, amount, and the like, the scope of the present technology is not necessarily limited to the number, amount, and the like unless otherwise stated particularly. Further, in the embodiments described below, each component is not necessarily essential to the present technology unless otherwise stated particularly. Further, the present technology is not limited to one that necessarily exhibits all the functions and effects stated in the present embodiment.

It should be noted that in the present specification, the terms “comprise”, “include”, and “have” are open-end terms. That is, when a certain configuration is included, a configuration other than the foregoing configuration may or may not be included.

Also, in the present specification, when geometric terms and terms representing positional/directional relations are used, for example, when terms such as “parallel”, “orthogonal”, “obliquely at 45°”, “coaxial”, and “along” are used, these terms permit manufacturing errors or slight fluctuations. In the present specification, when terms representing relative positional relations such as “upper side” and “lower side” are used, each of these terms is used to indicate a relative positional relation in one state, and the relative positional relation may be reversed or turned at any angle in accordance with an installation direction of each mechanism (for example, the entire mechanism is reversed upside down).

In the present specification, the term “battery” is not limited to a lithium ion battery, and may include other batteries such as a nickel-metal hydride battery and a sodium ion battery. In the present specification, the term “electrode” may collectively represent a positive electrode and a negative electrode.

In the present specification, the “battery cell” can be mounted on vehicles such as a hybrid electric vehicle (HEV), a plug-in hybrid electric vehicle (PHEV), and a battery electric vehicle (BEV). It should be noted that the use of the “battery cell” is not limited to the use in a vehicle.

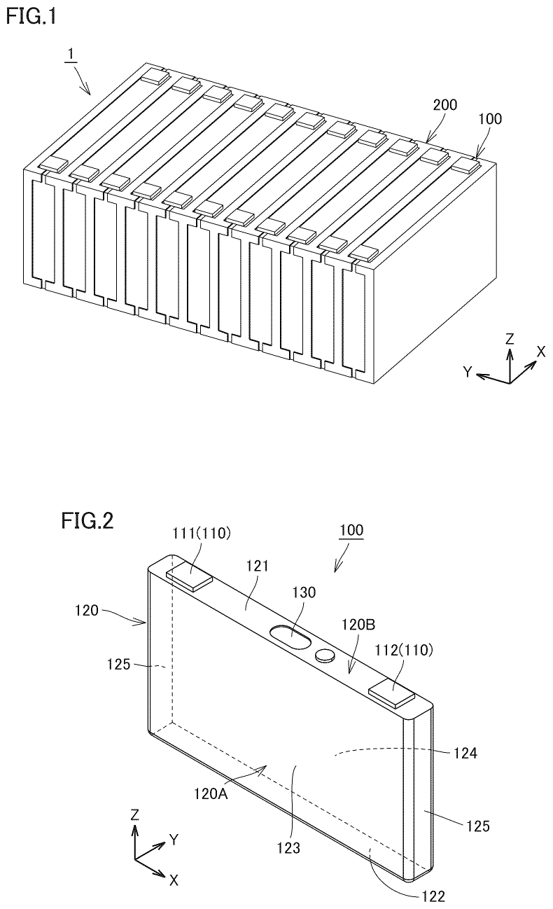

FIG. 1 is a perspective view of a battery assembly 1. As shown in FIG. 1, battery assembly 1 includes battery cells 100 and separator members 200.

Each of battery cells 100 is a prismatic battery cell, and the plurality of battery cells 100 are provided along a Y axis direction (first direction). Separator members 200 are provided between the plurality of battery cells 100. Each of separator members 200 prevents unintended electrical conduction between adjacent battery cells 100. Separator member 200 secures electrical insulation between adjacent battery cells 100.

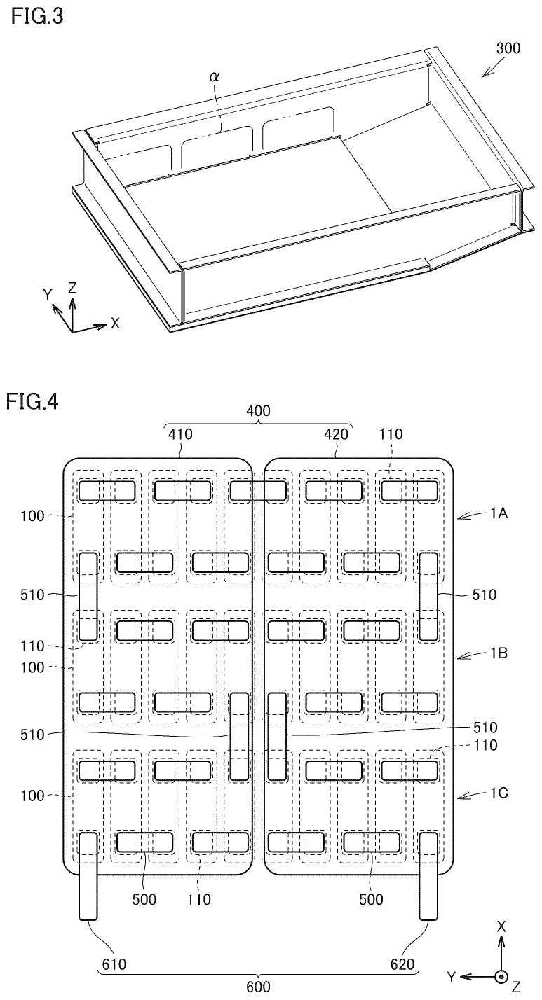

FIG. 2 is a perspective view showing each battery cell 100. As shown in FIG. 2, battery cell 100 has a prismatic shape. Battery cell 100 has electrode terminals 110, a housing 120, and a gas-discharge valve 130.

Electrode terminals 110 are formed on housing 120. Electrode terminals 110 have a positive electrode terminal 111 and a negative electrode terminal 112 arranged side by side along an X axis direction (second direction) orthogonal to the Y axis direction (first direction). Positive electrode terminal 111 and negative electrode terminal 112 are provided to be separated from each other in the X axis direction.

Housing 120 has a rectangular parallelepiped shape, and forms the external appearance of battery cell 100. Housing 120 includes: a case main body 120A that accommodates an electrode assembly (not shown) and an electrolyte solution (not shown); and a sealing plate 120B that seals an opening of case main body 120A. Sealing plate 120B is joined to case main body 120A by welding.

Housing 120 has an upper surface 121, a lower surface 122, a first side surface 123, a second side surface 124, and two third side surfaces 125.

Upper surface 121 is a flat surface orthogonal to a Z axis direction (third direction) orthogonal to the Y axis direction and the X axis direction. Electrode terminals 110 are disposed on upper surface 121. Lower surface 122 faces upper surface 121 along the Z axis direction.

Each of first side surface 123 and second side surface 124 is constituted of a flat surface orthogonal to the Y axis direction. Each of first side surface 123 and second side surface 124 has the largest area among the areas of the plurality of side surfaces of housing 120. Each of first side surface 123 and second side surface 124 has a rectangular shape when viewed in the Y axis direction. Each of first side surface 123 and second side surface 124 has a rectangular shape in which the X axis direction corresponds to the long-side direction and the Z axis direction corresponds to the short-side direction when viewed in the Y axis direction.

Basically, the plurality of battery cells 100 are stacked such that first side surfaces 123 of battery cells 100, 100 adjacent to each other in the Y direction face each other and second side surfaces 124 of battery cells 100, 100 adjacent to each other in the Y axis direction face each other (exceptions will be described later). At portions at which the plurality of battery cells 100 are stacked in this way, positive electrode terminals 111 and negative electrode terminals 112 are alternately arranged in the Y axis direction in which the plurality of battery cells 100 are stacked.

Gas-discharge valve 130 is provided in upper surface 121. When the temperature of battery cell 100 is increased (thermal runaway) and internal pressure of housing 120 becomes more than or equal to a predetermined value due to gas generated inside housing 120, gas-discharge valve 130 discharges the gas to outside of housing 120.

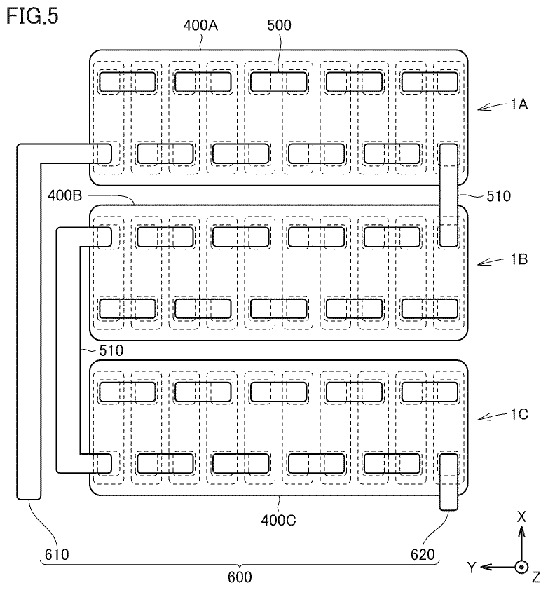

FIG. 3 is a perspective view showing a case member 300 that accommodates battery cells 100. In FIG. 3, for convenience of illustration, a cover portion of case member 300 is not shown.

As shown in FIG. 3, case member 300 defines an inner space that accommodates battery cells 100. Stacks (battery assemblies 1) of the plurality of battery cells 100 stacked in the Y axis direction are accommodated in the inner space of case member 300. In the example of FIG. 3, battery assemblies 1 are arranged in three rows in the X axis direction, but the number of rows of battery assemblies 1 is not particularly limited in a battery pack according to the present technology.

Side surface portions of case member 300 directly support the stacks of battery cells 100 while restraining the stacks in the Y axis direction (Cell-to-Pack structure). At portions α in FIG. 3, the stacks of battery cells 100 are in abutment with case member 300.

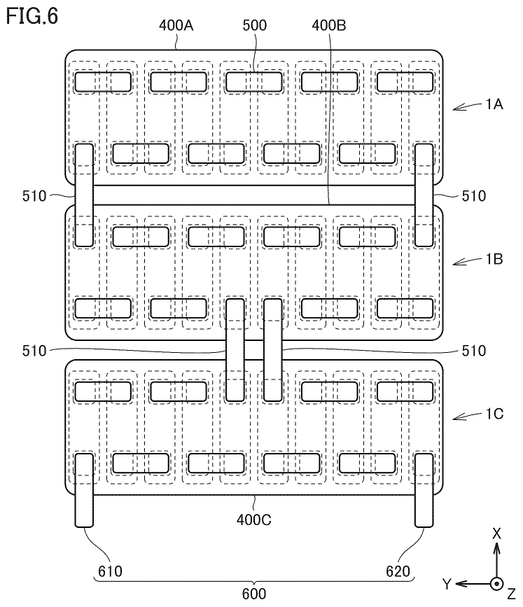

FIG. 4 is a diagram showing an arrangement of bus bar plates 400 and bus bars 500 in the battery pack according to the present embodiment. In the example shown in FIG. 4, a battery assembly 1A (first stack), a battery assembly 1B (second stack), and a battery assembly 1C (third stack) are provided to be arranged in three rows in the X axis direction. Three battery assemblies 1A, 1B, 1C are accommodated in case member 300 and are supported in the Y axis direction by case member 300.

Bus bar plates 400 include a bus bar plate 410 (first plate) and a bus bar plate 420 (second plate). A part (first group) of the plurality of bus bars 500 is mounted on bus bar plate 410. Another part (second group) of the plurality of bus bars 500 is mounted on bus bar plate 420. Bus bar plates 410, 420 are provided to be separated from each other.

Each of bus bar plates 410, 420 extends along the X axis direction (second direction) orthogonal to the Y axis direction so as to reach battery assembly 1B and battery assembly 1C from battery assembly 1A. Bus bar plate 410 and bus bar plate 420 are arranged side by side along the Y axis direction.

In each of battery assemblies 1A, 1B, 1C, positive electrode terminal 111 and negative electrode terminal 112 of adjacent battery cells 100 are connected to each other by bus bar 500. Bus bars 510 connect electrode terminals 110 of different battery assemblies among battery assemblies 1A, 1B, 1C. The plurality of battery cells 100 included in battery assemblies 1A, 1B, 1C are electrically connected in series by bus bars 500, 510.

A collective terminal bus bar 610 (positive-electrode-side collective terminal) and a collective terminal bus bar 620 (negative-electrode-side collective terminal) are provided as collective terminals for both polarities of battery assemblies 1A, 1B, 1C. Each of collective terminal bus bars 610, 620 is connected to battery assembly 1C. That is, collective terminal bus bars 610, 620 are located on the same side with respect to battery assemblies 1A, 1B, 1C in the X axis direction.

In the example of FIG. 4, battery assemblies 1A, 1B, 1C each include even and same number (10) of battery cells 100. Hence, the three rows of battery assemblies 1A, 1B, 1C include thirty battery cells 100 in total.

The widths of bus bar plates 410, 420 in the Y axis direction are the same. Hence, each of bus bar plates 410, 420 is disposed to cover fifteen battery cells 100.

Each of FIGS. 5 and 6 is a diagram showing an arrangement of bus bar plates 400A, 400B, 400C and bus bars 500 in a battery pack according to a reference example. Also in each of the examples shown in FIGS. 5 and 6, three battery assemblies 1A, 1B, 1C arranged in three rows in the X axis direction are provided.

In the reference example of FIG. 5, when collective terminal bus bars 610, 620 are drawn out from one side in the X axis direction (transverse direction), one collective terminal (collective terminal bus bar 610) is formed to be long and bus bar 510 connecting battery assembly 1B and battery assembly 1C is also formed to be long.

The long length of each of collective terminal bus bar 610 and bus bar 510 is a cause for increased manufacturing cost of the battery pack. Further, vibrations and shocks applied to bus bar 510 are increased.

In the reference example of FIG. 6, two bus bars 510 connecting battery assembly 1B and battery assembly 1C are joined to electrode terminals 110 of battery cells 100 located at an intermediate portion of battery assembly 1B in the Y axis direction and electrode terminals 110 of battery cells 100 located at an intermediate portion of battery assembly 1C in the Y axis direction. More specifically, bus bars 510 connecting battery assembly 1B and battery assembly 1C are provided in the vicinity of central portions of battery assemblies 1B, 1C in the Y axis direction.

In the reference example shown in FIG. 6, both collective terminal bus bars 610, 620 can be connected to battery assembly 1C by arranging bus bars 510 as described above. As a result, the length of each of bus bars 510 and collective terminal bus bar 610 in the X axis direction can be shorter than that in the example of FIG. 5.

According to bus bar plate 400 shown in FIG. 4, the same arrangement of bus bars 500, 510 as that in FIG. 6 is realized. Therefore, the length of each of bus bars 510 and collective terminal bus bar 610 in the X axis direction can be short.

Further, since two bus bar plates 410, 420 divided from each other in the Y axis direction (the stacking direction of battery cells 100) are used, a tolerance in the stacking direction of battery cells 100 can be facilitated to be absorbed. As a result, weldability of bus bar 500 can be improved.

Thus, in the battery pack according to the present embodiment, a connection structure for battery cells 100 by bus bars 500 is suppressed from being complicated. As a result, it is possible to provide a battery pack having high efficiency in mounting battery cells 100 and other components.

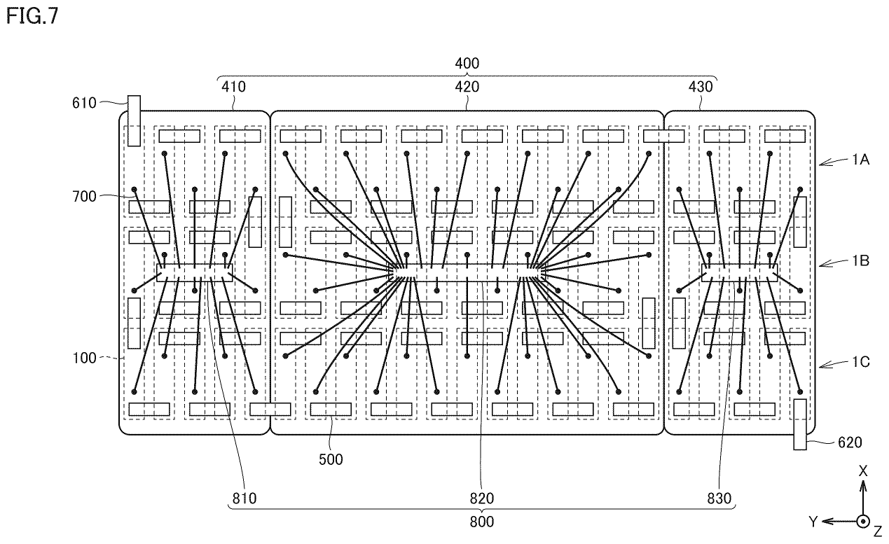

FIG. 7 is a top view showing an arrangement of bus bar plates 400 and bus bars 500 in a battery pack according to a modification.

Also in the modification shown in FIG. 7, a battery assembly 1A (first stack), a battery assembly 1B (second stack), and a battery assembly 1C (third stack) are provided to be arranged in three rows in the X axis direction.

Bus bar plates 400 include a bus bar plate 410 (first plate), a bus bar plate 420 (second plate), and a bus bar plate 430 (third plate). A part (first group) of the plurality of bus bars 500 is mounted on bus bar plate 410. Another part (second group) of the plurality of bus bars 500 is mounted on bus bar plate 420, and still another part (third group) of the plurality of bus bars 500 is mounted on bus bar plate 430. Bus bar plates 410, 420, 430 are provided to be separated from one another.

The plurality of battery cells 100 included in battery assemblies 1A, 1B, 1C are electrically connected in series by bus bars 500, 510.

A collective terminal bus bar 610 (positive-electrode-side collective terminal) and a collective terminal bus bar 620 (negative-electrode-side collective terminal) are provided as collective terminals for both polarities of battery assemblies 1A, 1B, 1C. Collective terminal bus bar 610 is connected to battery assembly 1A. Collective terminal bus bar 620 is connected to battery assembly 1C.

In the example of FIG. 7, each of battery assemblies 1A, 1B, 1C includes odd and same number (23) of battery cells 100. Hence, the three rows of battery assemblies 1A, 1B, 1C include sixty-nine battery cells 100 in total.

The widths of bus bar plates 410, 430 in the Y axis direction are the same. The width of bus bar plate 420 in the Y axis direction is larger than each of the widths of bus bar plates 410, 430 in the Y axis direction. That is, the widths of bus bar plates 410, 430 are different from the width of bus bar plate 420 in the Y axis direction.

Each of bus bar plates 410, 430 is disposed to cover fifteen battery cells 100 (five battery cells×three rows). Bus bar plate 420 is disposed to cover thirty-nine battery cells 100 (thirteen battery cells×three rows).

Voltage detection lines 700 are connected to respective battery cells 100. Voltage detection lines 700 are connected to outside of battery assemblies 1A, 1B, 1C via connectors 800.

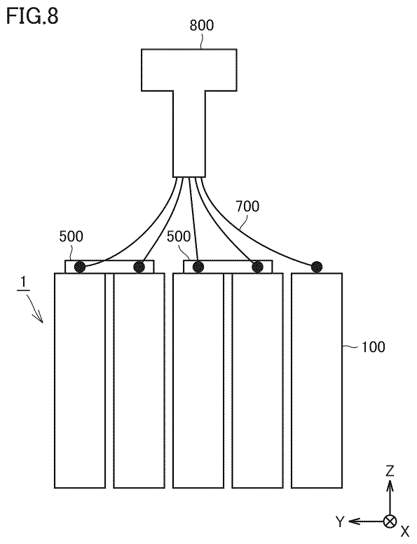

FIG. 8 is a diagram showing a state in which voltage detection lines 700 and connector 800 are viewed from a lateral side (X axis direction) of each battery cell 100. As shown in FIG. 8, the plurality of voltage detection lines 700 respectively connected to the plurality of battery cells 100 are collected in and connected to connector 800.

Referring again to FIG. 7, connectors 800 include a connector 810 (first connector), a connector 820 (second connector), and a connector 830 (third connector).

In connector 810, voltage detection lines 700 (first voltage detection lines) for battery cells 100 to which the plurality of bus bars 500 (first group) mounted on bus bar plate 410 are connected are collected. In connector 820, voltage detection lines 700 (second voltage detection lines) for battery cells 100 to which the plurality of bus bars 500 (second group) mounted on bus bar plate 420 are connected are collected. In connector 830, voltage detection lines 700 (third voltage detection lines) for battery cells 100 to which the plurality of bus bars 500 (third group) mounted on bus bar plate 430 are connected are collected.

In this way, voltage detection lines 700 are divided into the plurality of groups in the Y axis direction, and are collected in and connected to corresponding ones of connectors 810, 820, 830. Since voltage detection lines 700 and connectors 800 are disposed in this way, the lengths of voltage detection lines 700 can be short as a whole. As a result, impedances of voltage detection lines 700 are reduced.

In the example of FIGS. 7 and 8, it has been illustratively described that each voltage detection line 700 is constructed using a cable; however, also when the voltage detection line is constructed using a flexible printed circuit board, the same concept as that in the example of FIGS. 7 and 8 can be employed.

As described above, in the battery pack according to the present embodiment, the tolerance in the stacking direction of battery cells 100 can be facilitated to be absorbed, with the result that weldability of bus bar 500 can be improved and efficiency in mounting battery cells 100 and other components can be improved.

Since the tolerance in the stacking direction tends to be likely to be large when a large number (for example, 20 or more) of battery cells 100 are stacked, the arrangement of bus bar plates 400 and bus bars 500 as illustrated in the present embodiment is particularly effective.

Further, in the Cell-to-Pack structure in which case member 300 directly supports battery assembly 1, the arrangement of bus bars 500 and collective terminal bus bars 600 as illustrated in the present embodiment is particularly effective because battery cells 100 at end portions in the stacking direction are located close to the side walls of case member 300 and a remaining space in case member 300 is small.

It should be noted that the number (two or three in the above examples) of bus bar plates 400 divided and the widths thereof may be appropriately changed.

For example, when twenty-three battery cells are stacked in each of battery assemblies 1A, 1B, 1C as in the example of FIG. 7, the battery cells may be divided into three in the form of 3+17+3, into three in the form of 5+7+11, into five in the form of 3+3+11+3+3, or into five in the form of 3+5+7+5+3 in the Y axis direction. Further, the battery cells may be divided into two in the form of 2+21, into two in the form of 4+19, into four in the form of 2+9+10+2, or into four in the form of 4+7+8+4. These, inclusive of the number (23) of stacked battery cells 100, are merely illustrative.

Further, case member 300 is not limited to the one that directly supports battery assembly 1, and may be one (Cell-Module-Pack structure) that accommodates a battery module including battery assembly 1.

Although the embodiments of the present invention have been described and illustrated in detail, it is clearly understood that the same is by way of illustration and example only and is not to be taken by way of limitation. The scope of the present invention is defined by the terms of the claims, and is intended to include any modifications within the scope and meaning equivalent to the terms of the claims.

What is claimed is:

1. A battery pack comprising:
a first stack and a second stack each including a plurality of battery cells arranged side by side in a first direction;
a case that accommodates the first stack and the second stack;
a plurality of bus bars that electrically connect the plurality of battery cells;
a first plate on which a first group of the plurality of bus bars is mounted; and
a second plate on which a second group of the plurality of bus bars is mounted, the second plate being separated from the first plate, the second group being different from the first group, wherein
each of the first plate and the second plate extends along a second direction orthogonal to the first direction so as to reach the second stack from the first stack, and
the first plate and the second plate are arranged side by side along the first direction.

2. The battery pack according to claim 1, wherein
the plurality of battery cells included in the first stack and the second stack are electrically connected in series by the plurality of bus bars, and
a positive-electrode-side collective terminal and a negative-electrode-side collective terminal of the plurality of battery cells connected in series are located on the same side with respect to the first stack and the second stack in the second direction.

3. The battery pack according to claim 1, wherein each of the first group and the second group of the plurality of bus bars includes a bus bar that connects a battery cell included in the first stack to a battery cell included in the second stack.

4. The battery pack according to claim 1, wherein
the plurality of battery cells included in the first stack and the second stack are electrically connected in series by the plurality of bus bars,
a positive-electrode-side collective terminal and a negative-electrode-side collective terminal of the plurality of battery cells connected in series are located on the same side with respect to the first stack and the second stack in the second direction, and
each of the first group and the second group of the plurality of bus bars includes a bus bar that connects a battery cell included in the first stack to a battery cell included in the second stack.

5. The battery pack according to claim 1, further comprising:
a first connector in which first voltage detection lines for the plurality of battery cells to which the first group of the plurality of bus bars is connected are collected; and
a second connector in which second voltage detection lines for the plurality of battery cells to which the second group of the plurality of bus bars is connected are collected.

6. The battery pack according to claim 1, wherein
the plurality of battery cells included in the first stack and the second stack are electrically connected in series by the plurality of bus bars, and
a positive-electrode-side collective terminal and a negative-electrode-side collective terminal of the plurality of battery cells connected in series are located on the same side with respect to the first stack and the second stack in the second direction,
the battery pack further comprising:
a first connector in which first voltage detection lines for the plurality of battery cells to which the first group of the plurality of bus bars is connected are collected; and
a second connector in which second voltage detection lines for the plurality of battery cells to which the second group of the plurality of bus bars is connected are collected.

7. The battery pack according to claim 1, wherein
each of the first group and the second group of the plurality of bus bars includes a bus bar that connects a battery cell included in the first stack to a battery cell included in the second stack,
the battery pack further comprising:
a first connector in which first voltage detection lines for the plurality of battery cells to which the first group of the plurality of bus bars is connected are collected; and
a second connector in which second voltage detection lines for the plurality of battery cells to which the second group of the plurality of bus bars is connected are collected.

8. The battery pack according to claim 1, wherein
the plurality of battery cells included in the first stack and the second stack are electrically connected in series by the plurality of bus bars,
a positive-electrode-side collective terminal and a negative-electrode-side collective terminal of the plurality of battery cells connected in series are located on the same side with respect to the first stack and the second stack in the second direction, and
each of the first group and the second group of the plurality of bus bars includes a bus bar that connects a battery cell included in the first stack to a battery cell included in the second stack,
the battery pack further comprising:
a first connector in which first voltage detection lines for the plurality of battery cells to which the first group of the plurality of bus bars is connected are collected; and
a second connector in which second voltage detection lines for the plurality of battery cells to which the second group of the plurality of bus bars is connected are collected.

9. The battery pack according to claim 1, wherein
each of the first stack and the second stack includes even and same number of battery cells, and
widths of the first plate and the second plate in the first direction are the same.

10. The battery pack according to claim 1, wherein
the plurality of battery cells included in the first stack and the second stack are electrically connected in series by the plurality of bus bars,
a positive-electrode-side collective terminal and a negative-electrode-side collective terminal of the plurality of battery cells connected in series are located on the same side with respect to the first stack and the second stack in the second direction, and
each of the first group and the second group of the plurality of bus bars includes a bus bar that connects a battery cell included in the first stack to a battery cell included in the second stack,
the battery pack further comprising:
a first connector in which first voltage detection lines for the plurality of battery cells to which the first group of the plurality of bus bars is connected are collected; and
a second connector in which second voltage detection lines for the plurality of battery cells to which the second group of the plurality of bus bars is connected are collected, wherein
each of the first stack and the second stack includes even and same number of battery cells, and
widths of the first plate and the second plate in the first direction are the same.

11. The battery pack according to claim 1, wherein
each of the first stack and the second stack includes odd and same number of battery cells, and
widths of the first plate and the second plate in the first direction are different from each other.

12. The battery pack according to claim 1, wherein
the plurality of battery cells included in the first stack and the second stack are electrically connected in series by the plurality of bus bars,
a positive-electrode-side collective terminal and a negative-electrode-side collective terminal of the plurality of battery cells connected in series are located on the same side with respect to the first stack and the second stack in the second direction, and
each of the first group and the second group of the plurality of bus bars includes a bus bar that connects a battery cell included in the first stack to a battery cell included in the second stack,
the battery pack further comprising:
a first connector in which first voltage detection lines for the plurality of battery cells to which the first group of the plurality of bus bars is connected are collected; and
a second connector in which second voltage detection lines for the plurality of battery cells to which the second group of the plurality of bus bars is connected are collected, wherein
each of the first stack and the second stack includes odd and same number of battery cells, and
widths of the first plate and the second plate in the first direction are different from each other.

13. The battery pack according to claim 1, wherein the case supports the first stack and the second stack in the first direction.

14. The battery pack according to claim 1, wherein
the plurality of battery cells included in the first stack and the second stack are electrically connected in series by the plurality of bus bars,
a positive-electrode-side collective terminal and a negative-electrode-side collective terminal of the plurality of battery cells connected in series are located on the same side with respect to the first stack and the second stack in the second direction, and
each of the first group and the second group of the plurality of bus bars includes a bus bar that connects a battery cell included in the first stack to a battery cell included in the second stack,
the battery pack further comprising:
a first connector in which first voltage detection lines for the plurality of battery cells to which the first group of the plurality of bus bars is connected are collected; and
a second connector in which second voltage detection lines for the plurality of battery cells to which the second group of the plurality of bus bars is connected are collected, wherein
each of the first stack and the second stack includes even and same number of battery cells,
widths of the first plate and the second plate in the first direction are the same, and
the case supports the first stack and the second stack in the first direction.

15. The battery pack according to claim 1, wherein
the plurality of battery cells included in the first stack and the second stack are electrically connected in series by the plurality of bus bars, and
a positive-electrode-side collective terminal and a negative-electrode-side collective terminal of the plurality of battery cells connected in series are located on the same side with respect to the first stack and the second stack in the second direction, and
each of the first group and the second group of the plurality of bus bars includes a bus bar that connects a battery cell included in the first stack to a battery cell included in the second stack,
the battery pack further comprising:
a first connector in which first voltage detection lines for the plurality of battery cells to which the first group of the plurality of bus bars is connected are collected; and
a second connector in which second voltage detection lines for the plurality of battery cells to which the second group of the plurality of bus bars is connected are collected, wherein
each of the first stack and the second stack includes odd and same number of battery cells,
widths of the first plate and the second plate in the first direction are different from each other, and
the case supports the first stack and the second stack in the first direction.
